(19) United States
(12) Patent Application Publication
(10) Pub. No.: US 2009/0261839 A1
(43) Pub. Date: Oct. 22, 2009

(54) EFFLUENT IMPEDANCE BASED ENDPOINT DETECTION

(76) Inventors: Terry R. Turner, Austin, TX (US); Jerome Cannon, Austin, TX (US); Enlian Lu, Austin, TX (US)

Correspondence Address: HULSEY IP INTELLECTUAL PROPERTY LAWYERS, P.C., 919 Congress Avenue, Suite 919, AUSTIN, TX, 78701, US

(21) Appl. No.: 12/361,668

(22) Filed: Jan. 29, 2009

Related U.S. Application Data
(60) Provisional application No. 61/036,831, filed on Mar. 14, 2008.

(51) Int. Cl. G01N 27/62; G01R 27/00

(52) U.S. Cl. 324/459; 324/649

(57) ABSTRACT

A system to measure an impedance of an effluent associated with a foreline (effluent line or exhaust) is provided. This system includes a remote plasma source, a process chamber, an effluent line, an electrode assembly, an RF driver, and a detector. The remote plasma source couples to the process chambers and is operable to supply chamber-cleaning gas to the process chamber. The effluent line also couples to the process chamber where chamber-cleaning effluent exhausts the process chamber via the effluent line. The electrode assembly, located in the effluent line, is exposed to the effluent exhausting from the process chamber. The electrode assembly, coupled to the RF driver, receives an RF signal from the RF driver. The RF signal applied to the electrode assembly induces a plasma discharge within the electrode assembly and effluent line. A detector coupled to the electrode assembly detects an end point of a chamber clean of the process chamber. The end point may be detected based on a change in impedance associated with the plasma discharge within the electrode assembly and effluent line.

### CROSS-REFERENCE TO RELATED APPLICATIONS

The present U.S. Utility patent application claims priority pursuant to 35 U.S.C. § 119(e) to the following U.S. Provisional Patent Applications which are hereby incorporated herein by reference in their entirety and made part of the present U.S. Utility patent application for all purposes:

1. U.S. Provisional Application Ser. No. 61/036,831, entitled “END POINT DETECTION FOR REMOTE PLASMA CLEAN PROCESSES,” (Attorney Docket No. FRTH004USP) filed Mar. 14, 2008, pending.

### TECHNICAL FIELD OF THE INVENTION

The present disclosure relates generally to methods of monitoring and controlling processes associated with the fabrication of an electronic device, and more particularly, a system and method for controlling an etching process or chamber cleaning process. The chamber cleaning process may be done using a remote plasma source or by other chemical means.

### BACKGROUND OF THE INVENTION

Plasma Etch, dry chemical etch, Chemical vapor deposition (CVD) and plasma-enhanced chemical vapor deposition (PECVD) processes are vital components of semiconductor, flat panel display, photovoltaic technologies and textile manufacturing. Etching, either with plasma or simple reactive species is used to selectively remove films or otherwise perform surface treatments. CVD and PECVD processes are commonly used to deposit dielectric films at low temperatures to serve as either sacrificial layers or dielectric layers.

A non-value added, but essential, process step associated with depositing dielectric films using either CVD or PECVD involves plasma based cleaning of the process chamber and associated components. This clean removes residual film left after the deposition process. During the deposition process, the film is intentionally deposited on the work piece such as but not limited to a semiconductor substrate. Chamber cleans are performed after the semiconductor substrate has been removed from the chamber, and as such, are critical to the success of the deposition process but are not actually a part of semiconductor device fabrication. The common means for chamber clean steps is plasma based volatilization of the deposited film.

A fundamental principle employed in most plasma based processes is the disassociation of a chamber cleaning gas by the application of radio frequency (RF) power. As the chamber clean is an essential but non-value added process, the duration of the chamber clean should be minimized. Further, prolonged cleaning can actually degrade chamber components, thus resulting in the creation of yield limiting particles. Hence, in order to minimize manufacturing costs while maximizing step yields, endpoint detection of the chamber clean is imperative to stopping the cleaning process.

Many prior RF end point detection methods are based on monitoring the components of the delivered RF power. As the film clears from the chamber components, the by-products of the volatilized film volumetrically decrease in the plasma. This volumetric change in the plasma components creates an impedance change seen by the RF power delivery network, and results in consequential changes in the RF voltage, current, phase angle and self-bias voltage. By monitoring the changes in these signals, a correct determination of the RF end point may be obtained. Significantly, it is not necessary that the film type, film thickness or pattern density be consistent from run to run in order for the end point detector to properly function, since a signal analysis algorithm will be the compensating factor.

Various devices have been designed for monitoring the components of delivered RF power in semiconductor processing in order to determine end point of In Situ plasma chamber cleans.

### BRIEF SUMMARY OF THE INVENTION

Embodiments of the present disclosure are directed to systems and methods that are further described in the following description and claims. Advantages and features of embodiments of the present disclosure may become apparent from the description, accompanying drawings and claims.

According to one embodiment of the present disclosure a system to measure an impedance of a chamber clean effluent associated with a foreline (effluent line or exhaust line) is provided. This system includes a remote plasma source, a process chamber, an effluent line, an electrode assembly, an RF power delivery network, and a detector. The remote plasma source couples to the process chambers and is operable to supply chamber-cleaning gas to the process chamber. The effluent line also couples to the process chamber where chamber-cleaning effluent exhausts the process chamber via the effluent line. The electrode assembly, located in the effluent line, is exposed to the effluent exhausting from the process chamber. The electrode assembly, coupled to the RF power delivery network, receives an RF signal from the RF power delivery network. The RF signal applied to the electrode assembly induces a plasma discharge within the electrode assembly and effluent line. A detector coupled to the electrode assembly detects various components of the delivered RF signal to determine end point of a chamber clean of the process chamber. The end point may be detected based on a change in impedance associated with the plasma discharge within the electrode assembly and effluent line.

Another embodiment of the present disclosure a system to measure an impedance of a chamber clean effluent associated with a foreline is provided. This chamber clean may be a CVD tool process chamber clean performed with a chemical process that does not require RF or remote plasma source to activate the chemistry. This system includes a chamber cleaning gas source, a process chamber, an effluent line, an electrode assembly, a RF power delivery network, and a detector. The chamber cleaning gas source couples to the process chambers and is operable to supply chamber-cleaning gas to the process chamber. The effluent line also couples to the process chamber where chamber-cleaning effluent exhausts the process chamber via the effluent line. The electrode assembly, located in the effluent line, is exposed to the effluent exhausting from the process chamber. The electrode assembly, coupled to the RF power delivery network, receives an RF signal from the RF power delivery network. The RF signal applied to the electrode assembly induces a plasma discharge within the electrode assembly and effluent line. A detector coupled to the electrode assembly detects various components of the delivered RF signal to determine end point of a chamber clean of the process chamber. The end point may be detected based on a change in impedance associated with the plasma discharge within the electrode assembly and effluent line.

Another embodiment of the present disclosure provides a method of determining an end point of an etch process or a chamber clean process. This method involves coupling a remote plasma source to a process chamber. The remote plasma source may then supply a reactive specie (an etch gas or chamber cleaning gas) to the process chamber. Alternatively, a non activated etch gas or chamber cleaning gas may be supplied to the process chamber. Etch or chamber cleaning effluent exhausts the process chamber via an effluent line. An electrode assembly located within the exhaust line (foreline) is exposed to the etch or chamber cleaning effluent exhausting the process chamber. An RF signal may be applied to the electrode assembly wherein the RF signal induces a plasma discharge within the electrode assembly and effluent line. A detector samples one or more parameters associated with the plasma discharge within the electrode assembly and effluent line. The end point may then be determined based on the one or more sampled parameters associated with the plasma discharge.

Yet another embodiment associated with the present disclosure provides a device formed on a substrate. This device includes one or more deposited layers on the substrate. The deposited layers are deposited using a CVD or PECVD process within a process chamber of a process tool. After depositing a predetermined number of layers, the process chamber may be cleaned with chamber cleaning gas supplied from a remote plasma source coupled to the process chamber. An end point of the chamber clean may be determined by detection circuitry located in the foreline coupled to the CVD process chamber. The foreline exhausts chamber cleaning effluent from the CVD process chamber wherein an electrode assembly receives an RF signal and induces a plasma discharge within the chamber cleaning effluent within the foreline. Detection circuitry samples one or more parameters associated with the plasma discharge within the electrode assembly and foreline. The end point may then be determined based on the one or more sampled parameters associated with the plasma discharge. Such a device may be a semiconductor device, a display device, textile and/or a photo voltaic device.

Still yet another embodiment of the present disclosure provides an end point detector. This end point detector includes an electrode assembly, an RF driver, and detection circuitry. The electrode assembly may be located in an effluent line of a process chamber. The electrode assembly is exposed to chamber cleaning effluent exhausting from the process chamber. An RF driver coupled to the electrode assembly applies an RF signal to the electrode assembly wherein this RF signal induces a plasma discharge within the chamber cleaning effluent located proximate to the electrode assembly and effluent line. The detection circuitry couples to the electrode assembly and is operable to sample various parameters associated with the plasma discharge and determine an end point of a chamber clean based on the sample plasma discharge.

Yet another embodiment of the present disclosure provides an end point detector. This end point detector includes an electrode assembly, RF driver, detection circuitry, and interface circuitry. The electrode assembly may be located in an effluent line coupled to a process chamber. The electrode assembly may be exposed to chamber cleaning effluent exhausting from the process chamber. An RF driver coupled to the electrode assembly applies an RF signal to the electrode assembly. This RF signal induces a plasma discharge within the electrode assembly and effluent line. Detection circuitry coupled to the electrode assembly samples parameters associated with the plasma discharge. The interface circuitry couples to a process tool, a remote plasma source, the RF driver, and the detection circuitry. The interface circuitry may receive a trigger signal from the remote plasma source wherein the RF signal is initiated by the RF driver based on the received trigger signal. The interface circuitry may also supply various signals based on sampled parameters associated with the plasma discharge to processing circuitry within the process tool. Processing circuitry within the process tool may determine an end point signal from the various signals based on sampled parameters associated with the plasma discharge and secure chamber cleaning gas to the process chamber based on the end point signal.

### BRIEF DESCRIPTION OF THE SEVERAL VIEWS OF THE DRAWINGS

For a more complete understanding of the present disclosure and the advantages thereof, reference is now made to the following description taken in conjunction with the accompanying drawings in which like reference numerals indicate like features and wherein:

FIGS. 1A and 1B depict the relationship between the impedance magnitude of the plasma discharge versus the NF3 partial pressure and the relationship of phase to NF3 partial pressure respectively.

FIG. 2 is a block diagram illustrating a prior art RF measurement location for in situ chamber cleans;

FIG. 3 provides a graph of typical impedance data from an in situ RF chamber clean;

FIGS. 4A and 4B provide block diagrams of an effluent impedance based endpoint detector in accordance with embodiments of the present disclosure;

FIG. 5 provides a second block diagram of an effluent impedance based endpoint detector in accordance with embodiments of the present disclosure;

FIGS. 6A, 6B and 6C depict examples of an electrode assembly in accordance with embodiments of the present disclosure;

FIG. 7 provides a graph showing voltage, current and phase from a remote plasma clean on a Novellus Sequel PECVD tool in accordance with embodiments of the present disclosure;

FIG. 8 provides a graph showing how the phase signal changes over time and that signal is dominated by changes in chemistry and not pressure;

FIG. 9 provides a graph showing how plasma impedance is driven by chemistry; and

FIG. 10 provides a logic flow diagram associated with a method operable to determine an end point in a remote plasma source (RPS) cleaned deposition system in accordance with embodiments of the present disclosure.

### DETAILED DESCRIPTION OF THE INVENTION

Preferred embodiments of the present disclosure are illustrated in the FIGs., like numerals being used to refer to like and corresponding parts of the various drawings.

The present disclosure provides a system to measure an impedance of an effluent associated with a foreline (effluent line or exhaust line) that substantially addresses the above identified needs. This system includes a remote plasma source, a process chamber, an effluent line, an electrode assembly, an RF power delivery network, and a detector. The remote plasma source couples to the process chambers and is operable to supply chamber-cleaning gas to the process chamber. The effluent line also couples to the process chamber where chamber-cleaning effluent exhausts the process chamber via the effluent line. The electrode assembly, located in the effluent line, is exposed to the effluent exhausting from the process chamber. The electrode assembly, coupled to the RF driver, receives an RF signal from the RF driver. The RF signal applied to the electrode assembly induces a plasma discharge within the electrode assembly and effluent line. A detector coupled to the electrode assembly detects various components of the delivered RF signal to determine end point of a chamber clean of the process chamber. The end point may be detected based on a change in impedance associated with the plasma discharge within the electrode assembly and effluent line.

The process chamber described above may be used to perform Plasma Etch, dry chemical etch, Chemical vapor deposition (CVD) and plasma-enhanced chemical vapor deposition (PECVD) processes. For the purposes of explanation this disclosure focuses on both CVD and PECVD processing. However, embodiments of the present disclosure may be applied to the various identified processes and other like processes known to those having skill in the art.

The concept of monitoring changes in the RF load impedance for the purpose of chamber clean endpoint detection was disclosed in U.S. Pat. No. 5,576,629 (Turner et. al) which is hereby incorporated by reference for all purposes. Turner et. al. teaches the concept of monitoring the components of impedance (voltage, current and phase angle) to detect transitions which indicate a chemical change in the plasma component of the RF load. PECVD and CVD processes used in semiconductor manufacturing have historically relied on in situ RF chamber cleans to remove the deposited film(s) from chamber walls and chamber components. Hence, inserting a measurement device at the point of use of the RF power provided the optimal voltage (V), current (I) and phase angle (Φ) data stream for use in clean endpoint detection.

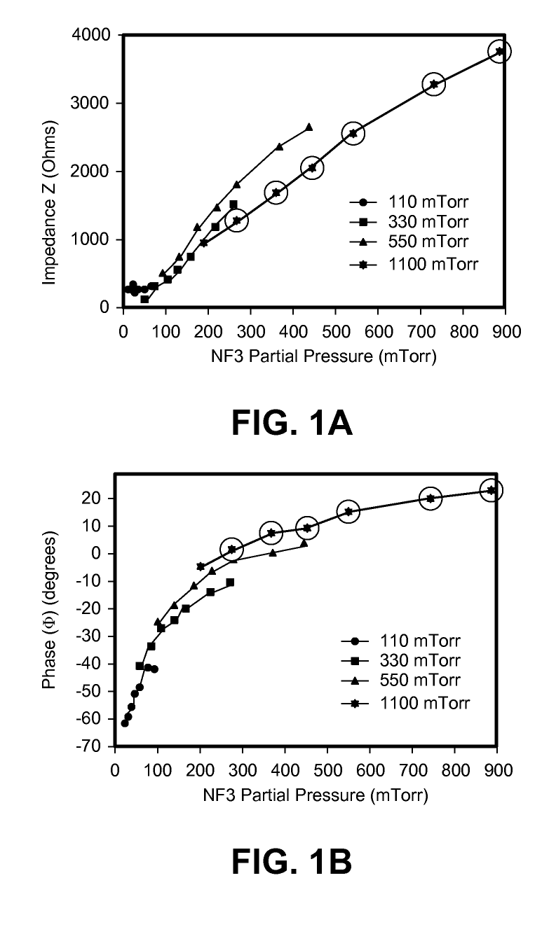

FIGS. 1A and 1B depict the relationship between the impedance magnitude of the plasma discharge versus the NF3 partial pressure and the relationship of phase to NF3 partial pressure respectively. These charts illustrate the sensitivity of the complex RF load impedance (plasma impedance) to the concentration of a clean gas such as NF3. “Optimizing utilization efficiencies in electronegative discharges: The importance of the impedance phase angle,” W. R. Entley, J. G. Langan, B. S. Felker, and M. A. Sobolewski, J. Appl. Phys. 86 (9) 4825-4835 (1999)

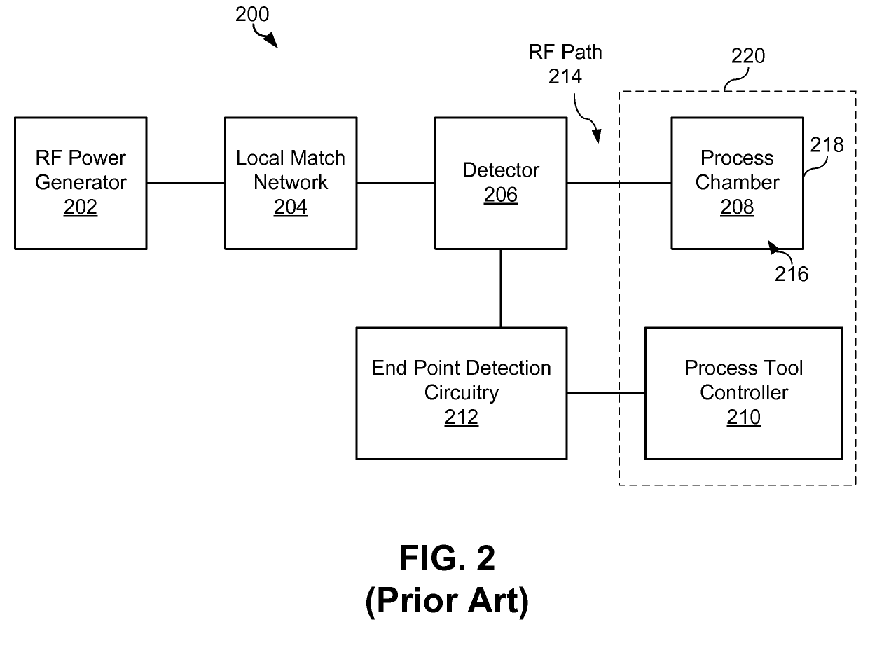

FIG. 2 is a block diagram illustrating a prior art RF measurement location for in situ chamber cleans. This prior art arrangement includes RF power generator 202, local match network 204, detector 206, process chamber 208, tool controller 210, and end point detection circuitry 212. In this arrangement RF power is provided to the process chamber via RF path 214 to process chamber 208 in order to activate a chamber cleaning gas 216. Detector 206 may be a Sense Rite® RF Sensor provided by Forth-Rite® Technologies, LLC. Such a sensor is disclosed in U.S. Pat. Nos. 7,345,428, and 7,403,764 which are hereby incorporated by reference for all purposes. As shown here detector 206 is installed “post-match” at the “point-of-use” for RF power. This detector may include fully functional stand-alone software for data acquisition and viewing; and be integrated into data acquisition systems for higher level fault detection and classification applications.

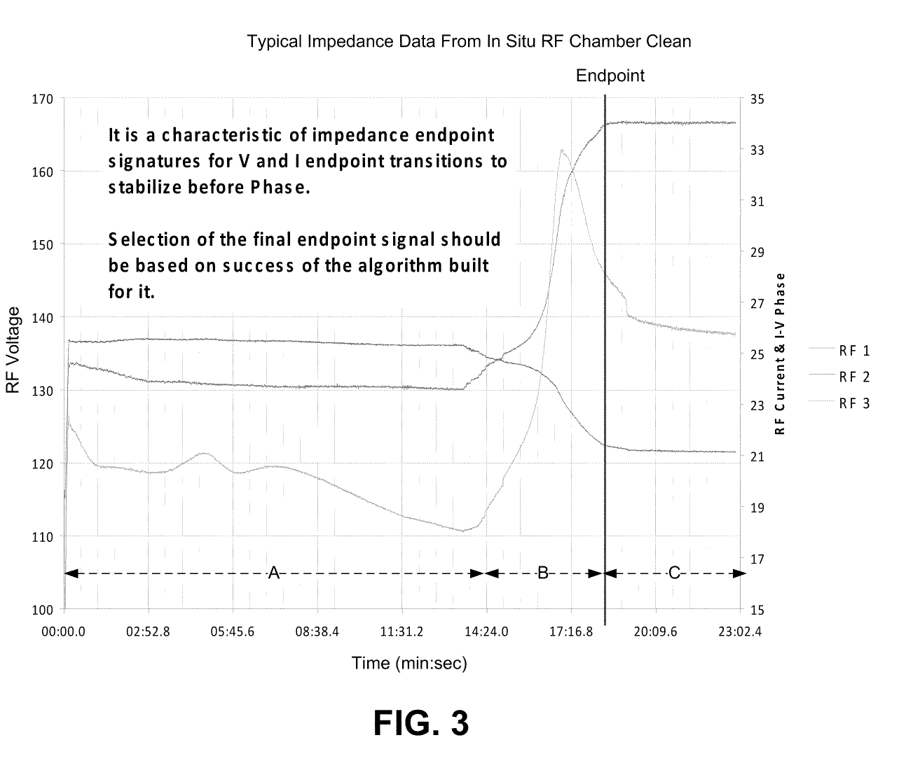

FIG. 3 provides a graph of typical impedance data from an in situ RF chamber claim. Such information is associated with the prior art arrangement of FIGS. 1A, 1B and FIG. 2.

Unlike complex and often difficult to interpret optical emission endpoint data, impedance based endpoint detection data is simple to interpret. At the initiation of the chamber clean process, film is being removed from all parts of the chamber. Since volumetrically the effluent is not changing, neither does the plasma chemistry which drives the RF load impedance. The result is an insignificant (if any) change in some or all of the components of impedance as are seen in region “A” of the traces in FIG. 3. (It should be pointed out here that often Φ is the most sensitive component and displays early warning of an impending chemical transition.) However, as the film begins to clear, volumetrically the amount of effluent present in the plasma chemistry begins to change creating the transitions in V, I and Φ seen in region “B” of FIG. 3. Transitions in V and I are typically singular in nature for single films and stepped for stacked films. These transitions continue until the plasma chemistry re-stabilizes (region “C”) at which time the effluent component of the plasma impedance has gone and we are left with the impedance corresponding to only the clean chemistry itself. Hence, interpretation of impedance based endpoint traces is simply a region of stability where the film is being etched everywhere, followed by a region of transition created by the film clearing and when the impedance components return to a stable value the process is completed.

Etching film from all surfaces in the chamber (region A); film clearing thereby volumetrically changing the effluent component of the plasma impedance (region B); and cleared with no effluent component remaining in the plasma impedance (region C).

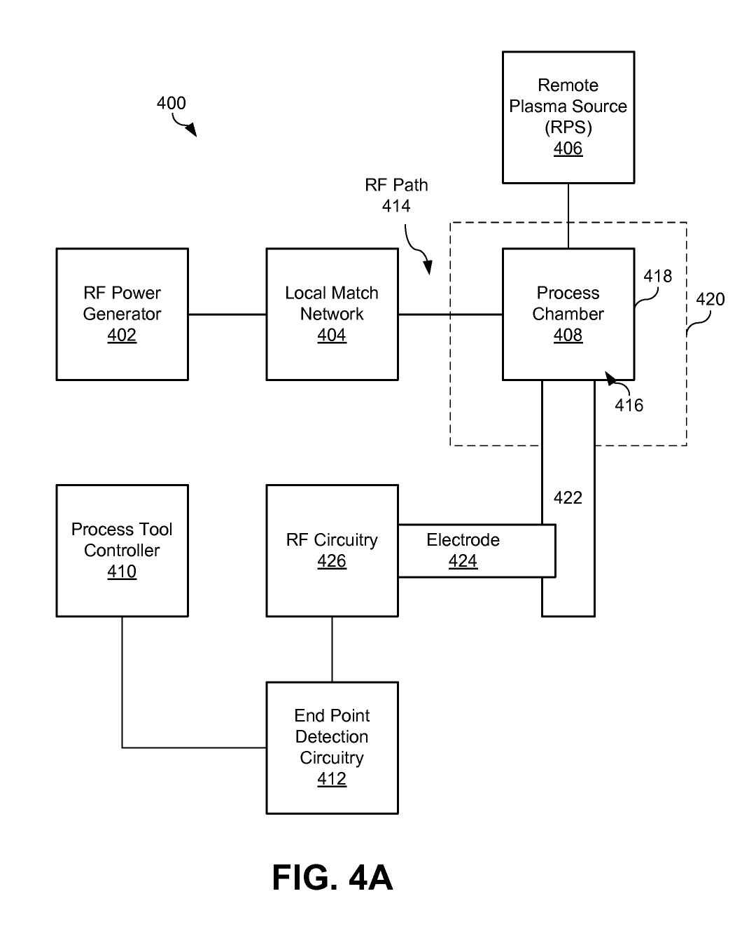

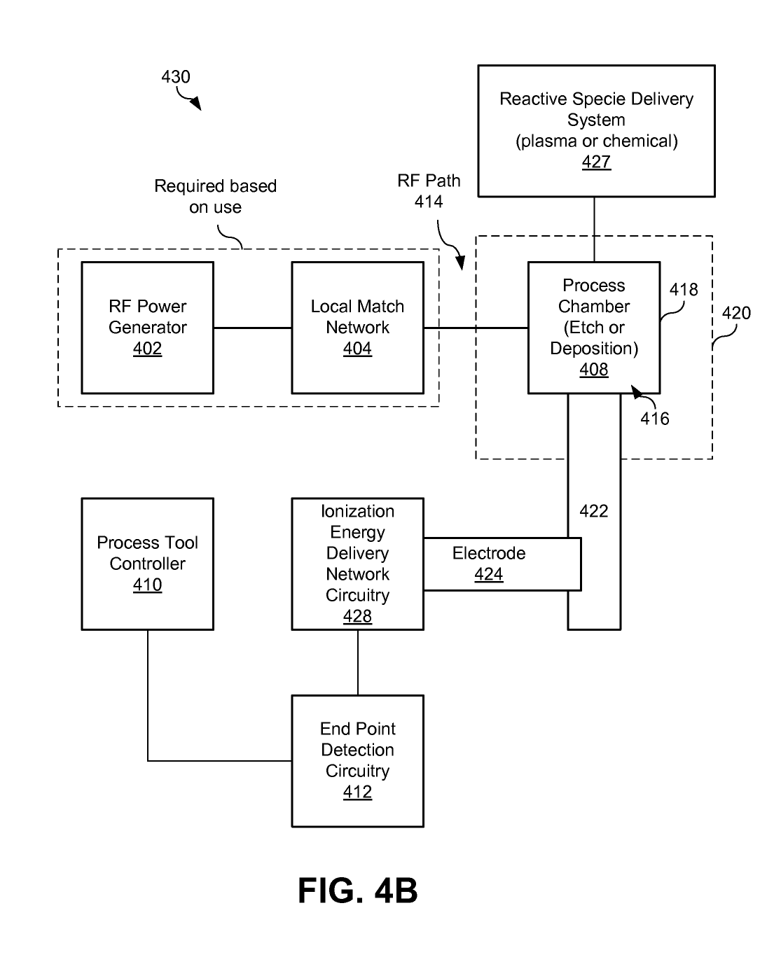

Impedance based endpoint detection for in situ RF chamber cleans is simple to implement, robust in operation, does not suffer any form of degradation, is cost effective and due to the difference in signal to noise ratio better performing than any other technology. However, chamber clean technology has evolved and many tools (semiconductor, display and solar) now use remote plasma clean (RPC) technology. This means that there is no RF power supplied to the clean process via the primary path. However, impedance based endpoint detection is still the most viable solution when properly implemented into the chamber foreline as seen in FIG. 4.

FIG. 4A provides a block diagram of an effluent impedance monitoring system used to detect endpoints in accordance with embodiments of the present disclosure. System 400 includes the RF power generator 402, local match network 404, remote plasma source 406, process chamber 408, process tool controller 410, RF circuitry 426, an electrode assembly 424, foreline 422 and end point detection circuitry 412. The remote plasma source 406 couples to the process chamber 408 within process tool 420. The remote plasma source 406 may provide a chamber cleaning gas 416 used on components and chamber walls 418 in the process chamber after a predetermined amount of depositions. The primary RF power delivery path (402 and 404) may or may not be present (as in the case of BPSG which is a CVD process). However, tools providing such CVD processes may still use an RPS for chamber clean. The chamber cleaning gas effluent is evacuated or exhausted through foreline 422. Embodiments of the present disclosure place an electrode assembly 424 in the environment of foreline 422. This electrode is exposed to the chamber-cleaning effluent. An RF signal produced by RF circuitry 426 is applied to electrode assembly 424 and may initiate or induce a local plasma discharge proximate to the electrode assembly 424 and foreline 422. The RF circuitry shown here may include detection circuitry which may sample voltage, current, phase, impedance, reflected RF power or other like parameters associated with the RF signal. Such circuitry may include the Sense-Rite® technology and Trace-Rite® technology provided by Forth-Rite® Technologies. An endpoint detection circuitry couples to and receives the one or more sampled parameters associated with the localized plasma discharge in order to determine an endpoint of the chamber cleaning process.

By creating a small plasma in the chamber foreline, extremely effective impedance based endpoint detection may be implemented on tools using RPC technology.

The electrode assembly 424 is exposed to the foreline environment (pressure and chemistry) such that when RF power is applied to the electrodes a small discharge is created in the foreline consisting of the clean process effluent.

FIG. 4B provides another block diagram of an effluent impedance monitoring system used to detect endpoints in accordance with embodiments of the present disclosure. System 430 includes the RF power generator 402, local match network 404, reactive specie delivery system 427, process chamber 408, process tool controller 410, ionization energy delivery network circuitry 428, an electrode assembly 424, foreline 422 and end point detection circuitry 412. The reactive specie delivery system 426 couples to the process chamber 408 within process tool 420. The reactive specie delivery system 406 may provide a etch gas or chamber cleaning gas 416 used within etch processes on various layers or chamber cleaning processes on components and chamber walls 418 in the process chamber after a predetermined amount of depositions.

The system provided in FIG. 4B is similar to that of FIG. 4A except that FIG. 4B is not limited to an activated etchant or chamber cleaning gas. The reactive specie delivery system operable to supply reactive species, the reactive species may volatilize a film in the process chamber. As previously stated with reference to FIG. 4A, the primary RF power delivery path (402 and 404) may or may not be present (as in the case of BPSG which is a CVD process). Such CVD processes may still use an RPS for chamber cleans. The volatilized film effluent is evacuated or exhausted through foreline 422. An electrode assembly 424 in the environment of foreline 422 is exposed to the volatilized film effluent. Ionizing energy produced by ionization energy delivery network circuitry 428 is applied to electrode assembly 424 and may initiate or induce a local plasma discharge proximate to the electrode assembly 424 and foreline 422. The ionizing energy signal applied at the electrode assembly induces a plasma discharge within the electrode assembly and effluent line. Although one embodiment may use 13.56 MHz, other embodiments may use any ionizing energy from DC to 100 MHz or higher. The ionization energy delivery network shown here may include detection circuitry which may sample voltage, current, phase, impedance, reflected RF power or other like parameters associated with the ionizing energy signal. Such circuitry may include the Sense-Rite® technology and Trace-Rite® technology provided by Forth-Rite® Technologies. An endpoint detection circuitry couples to and receives the one or more sampled parameters associated with the localized plasma discharge in order to determine an endpoint of the chamber cleaning process.

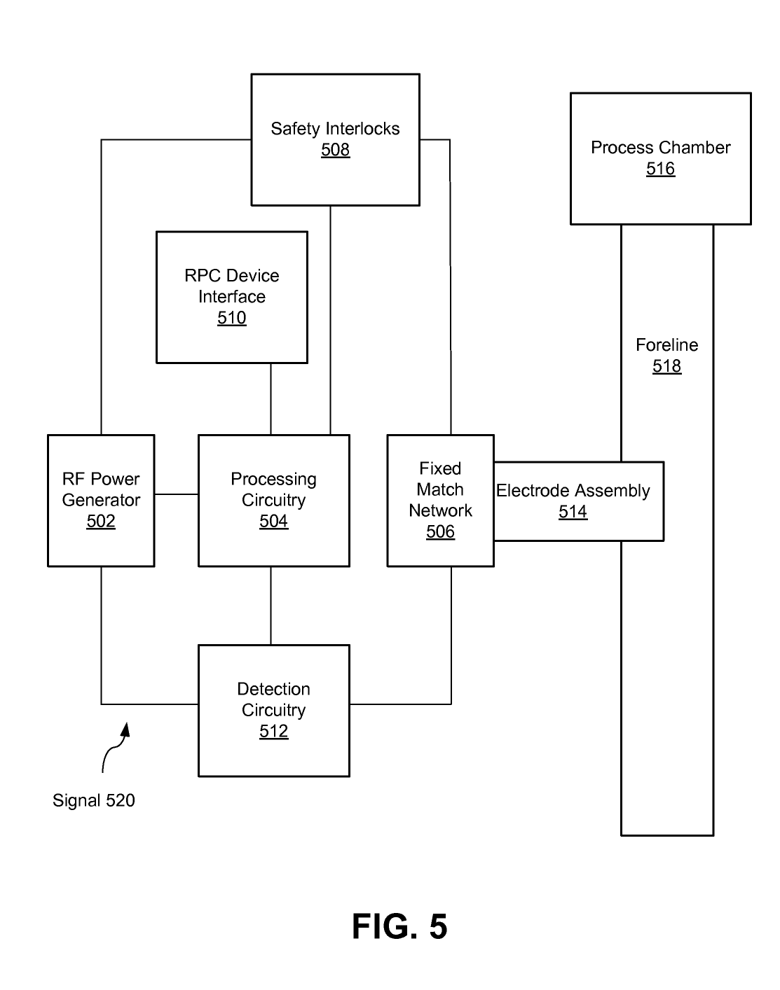

FIG. 5 provides a second block diagram of an effluent impedance based endpoint detector in accordance with embodiments of the present disclosure. System 500 includes a RF power generator 502, processing circuitry 504, fixed match network 506, safety interlocks 508, remote plasma cleaning device interface 510, endpoint detection circuitry 512, electrode assembly 514, process chamber 516 and foreline 518. RF power generator 502 provides an RF signal through detection circuitry 512 and fixed match network 506 in order to provide the RF signal to electrode assembly 514. This RF signal may generate a localized plasma discharge in the foreline 518. The environment within the foreline during a chamber cleaning is the chamber cleaning effluent exiting process chamber 516. Processing circuitry 504 may interface with the RF power generator 502, RPC device interface 510, and safety interlocks 508. This allows a trigger signal. In certain environments a trigger signal from the RPC device interface 510 may be provided in order to initiate the RF signal 520 from RF power generator 502 via processing circuitry 504. Processing circuitry 504 may also determine gain, offset RF set point, RF reflected power and RF provided power as well as containing circuitry and software for stand-alone data presentation and analysis. Such analysis may include endpoint detection. Safety interlocks 508 may determine vacuum, case integrity and RF power in order to allow the fixed match network to provide the RF signal to electrode assembly 514.

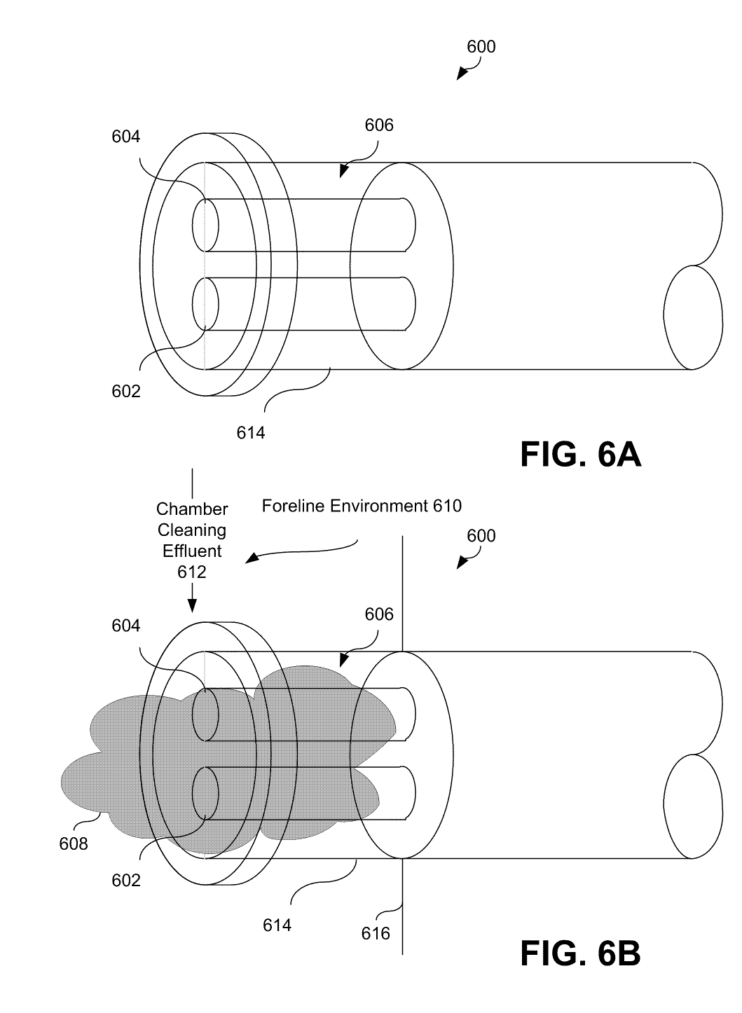

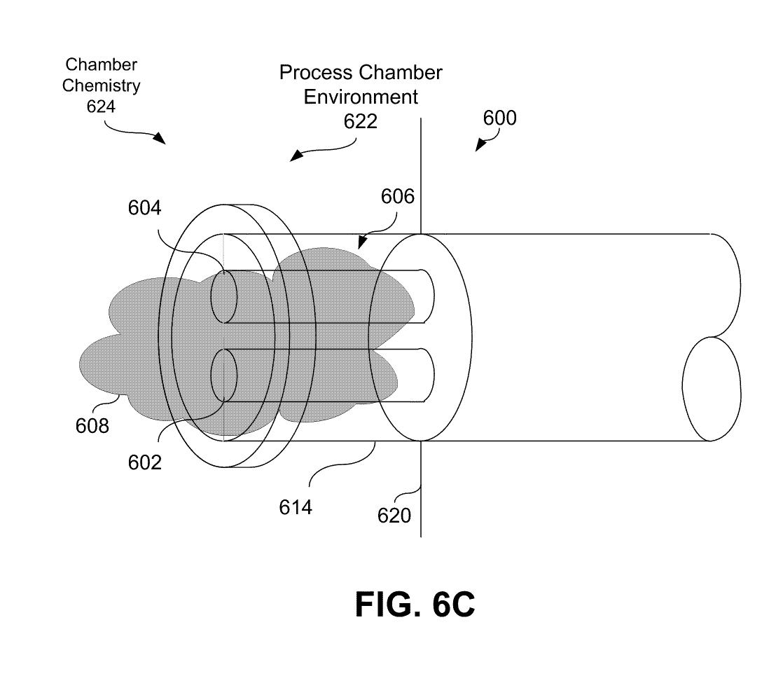

FIGS. 6A, 6B and 6C depict examples of an electrode assembly 600 in accordance with embodiments of the present disclosure. Electrode assembly 600 includes electrode 602 and 604 which may be placed within a well-defined cavity or space 606. As shown in FIG. 6B electrode assembly may be placed in the foreline environment 610 where the electrodes are exposed to the chamber cleaning effluent 612. Other embodiments may place the electrode assembly in the chamber environment where the electrodes are exposed to the chamber environment chemistry. When an RF signal is applied to electrodes 602 and 604 a localized plasma discharge 608 will be induced. The primary discharge may be between the electrode 604 and 602 and the cavity wall 614. Since the electrodes are in the proximity of the foreline wall 616 the discharge 608 will extend into the foreline. FIG. 6C shows the electrode assembly 600 in the chamber environment 622 where the electrodes are exposed to the chamber environment chemistry 624. the electrodes in FIG. 6C are in the proximity of the chamber wall 620 the discharge 608 will extend into the chamber. Electrode assembly 600 may be fabricated using either stainless steel or Ni electrodes contained within a well defined cavity space 606. Embodiments of the present disclosure allow chemical processes to be monitored. Although chemical changes in volatized chemistry associated with etch process are discussed, chemical changes that occur due to thermal processes may also be monitored.

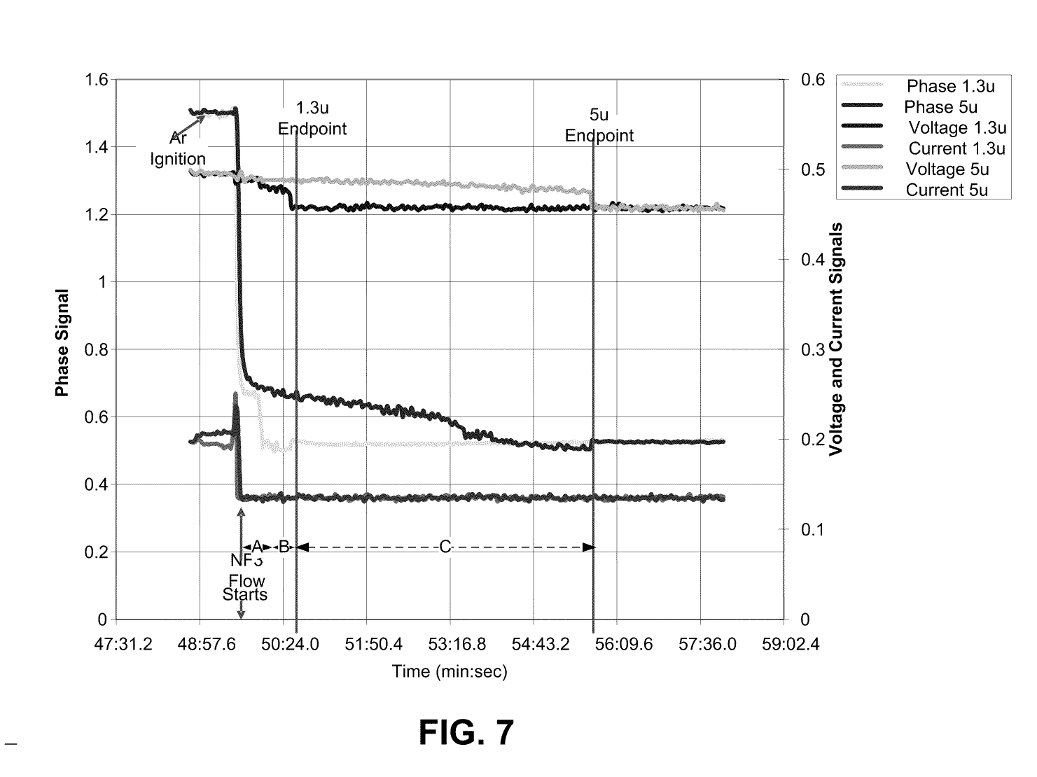

The use of common 13.56 MHz RF power (at a low level) to create a small localized plasma 608, allows for the application of the combination measurement technology and end-point detection circuitry and software with process tool integration hardware to the problem of RPC endpoint detection. With no optical path to maintain, the self-cleaning action of exposure to the clean chemistry in a plasma environment keeps the electrode surfaces and surrounding cavity pristine. Identical in function to that used in the in situ RF clean technology, the data from detection circuitry is easy to interpret (see FIG. 7) making a viable solution for PECVD/CVD RPC chamber cleaning endpoint detection available.

FIG. 7 provides a graph showing voltage, current and phase from a remote plasma clean on a Novellus Sequel tool. At the initiation of the chamber clean process in Region “A”, film is being removed from all parts of the chamber. Since volumetrically the effluent is not changing, neither does the plasma chemistry which drives the RF load impedance. The result is an insignificant (if any) change in some or all of the components of impedance as are seen in region “A” of the traces in FIG. 7. However, as the film begins to clear, volumetrically the amount of effluent present in the plasma chemistry begins to change creating the transitions in V, I and Φ seen in region “B” of FIG. 7. Transitions in V and I are typically singular in nature for single films and stepped for stacked films. These transitions continue until the plasma chemistry re-stabilizes (region “C”) at which time the effluent component of the plasma impedance.

Impedance based endpoint detection for RPC chamber cleans is simple to implement, robust in operation and does not suffer any form of degradation and is cost effective and due to the difference in signal to noise ratio better performing than any other technology.

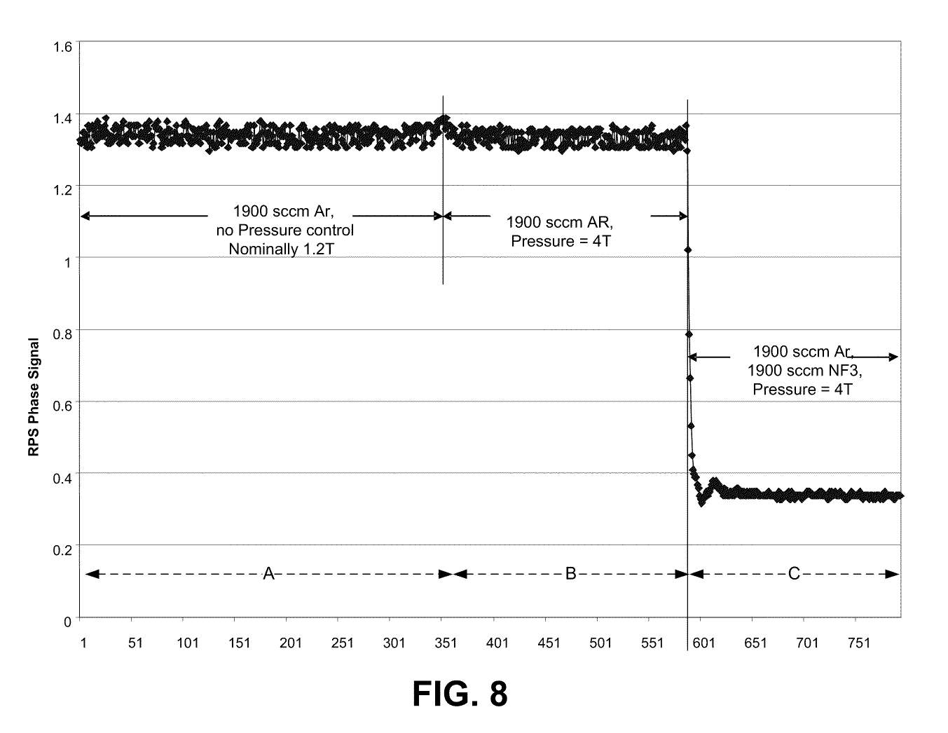

FIG. 8 provides a graph showing how the phase signal changes over time and that signal is dominated by changes in chemistry. In Region “A” 1900 sccm of argon (Ar) is provided with no pressure control. In Region “B” pressure is controlled at 4 Torr (T). In Region “C” a mixture of Ar and NF3 at 4 T is provided. From these three regions one can clearly see that the changing chemistry that occurred between Regions “B” and “C” clearly show how chemistry influences dominate the detected phase signal.

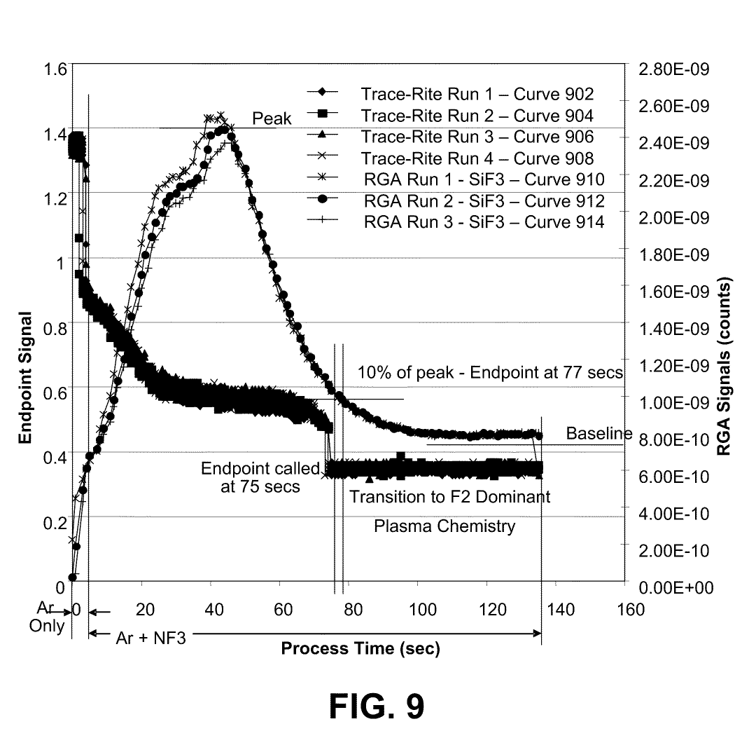

FIG. 9 provides a graph showing how plasma impedance is driven by chemistry. This graph shows a data from a residual gas analyzer (RGA), and an effluent impedance based endpoint signal versus time. In Region “A” only argon is provided. In Region B argon and NF3 are provided to the chamber. Curves 902, 904, 906 and 908 are impedance-based signals while curves 910, 912 and 914 are RGA analysis based signals. End point occurs at 75 seconds according to the impedance-based signals. After this there is a transition to Fluorine dominant plasma chemistry. FIG. 9 clearly shows that the plasma impedance is driven by the change of chemistry in the chamber cleaning effluent.

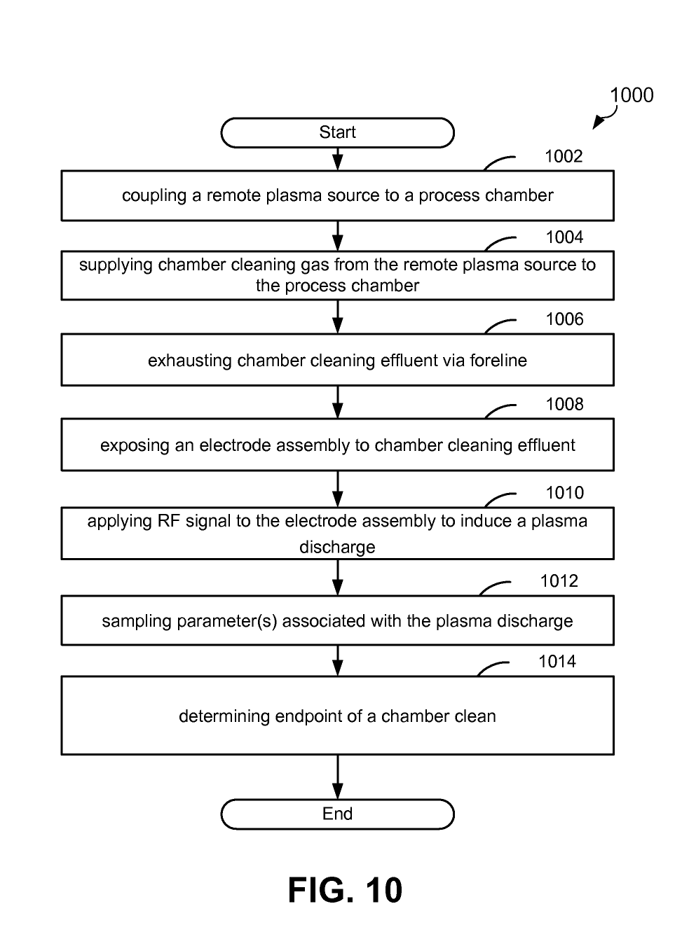

FIG. 10 provides a logic flow diagram associated with a method operable to determine an End point in a RPS system in accordance with embodiments of the present disclosure. Operations 1000 of this method begin at Block 1002 where remote plasma source (RPS) couples to a process chamber. In Block 1004 chamber cleaning gas may be supplied from the RPS to the process chamber. In Block 1006 chamber cleaning effluent is exhausted from the process chamber via a foreline. In Block 1008 an electrode assembly located in the foreline is exposed to the chamber cleaning effluent. In Block 1010 an RF signal is applied to the electrode assembly. This RF signal induces a plasma discharge within the electrode assembly and foreline. In Block 1012 one or more parameters associated with the plasma discharge are sampled. These parameters may include voltage associated with RF signal, current associated with RF signal, a phase associated with the RF signal, a delivered power of the RF signal and impedance of the RF signal, a resistance of the RF signal, a generator forward or reflected power associated with the RF signal, and/or reactance (X) of the RF signal. In Block 1014 end point circuitry may determine the end point of a chamber cleaning based on the one or more sampled parameters associated with the plasma discharge. These parameters may be analyzed, combined, ratio-ed, or otherwise operated on to identify chemical changes in the process chamber.

This method may further include initiating the RF signal with a trigger signal provided by the RPS. In this way the RF signal in the fore line is only applied during the clean to determine when end point of the clean is reached. During non-clean periods there is no reason to induce a plasma in the foreline. This chamber clean may be secured based on the determined end point. Securing the chamber clean may involve both securing the supply of chamber cleaning gas from the RPS to the process chamber and securing the RF signal applied to the electrode assembly. This chamber clean may occur within a process chamber of a CVD process tool or a PECVD process tool. The deposited layers manufactured within the process tool are part of a device such as a semiconductor device, a display device or a photo voltaic device.

Processing circuitry within the process tool may couple to the detector that samples one or more parameters associated with the plasma discharge. The detector may either provide the raw sampled parameter signals wherein the process tool then determines the end point based on the supplied signals. Alternatively the detector may determine the end point and provide an end point signal to the process tool.

Another embodiment may provide a device such as a semiconductor device, photo voltaic device, or display device manufactured on a substrate using a CVD or PECVD process. Additionally, the layers deposited using the CVD or PECVD process may be a protective or decorative layer deposited on a work piece such as textile, lens, glass substrate (such as but not limited to architectural glass), or even a piece of jewelry. One or more layers may be deposited during the manufacturing of the device on the substrate within a process chamber of a process tool. The process chamber may be periodically cleaned with chamber cleaning gas supplied by a RPS coupled to the CVD process chamber. An end point of the chamber cleaning may be determined by detection circuitry located in a foreline coupled to the CVD process chamber. The foreline exhausts chamber cleaning effluent from the CVD process chamber while the detection circuitry induces and samples parameters associated with the plasma discharge within the chamber cleaning effluent within the foreline. By examining the impedance or other parameters associated with the plasma discharge it is possible to determine an end point of the chamber clean.

In summary, the present disclosure provides a system to measure an impedance of an effluent associated with a foreline (effluent line or exhaust line). This system may or may not include a RPS, a process chamber, an effluent line, an electrode assembly, an RF driver, and a detector. Chamber-cleaning gas is supplied to the process chamber either with or without an RPS. The effluent line also couples to the process chamber where chamber-cleaning effluent exhausts the process chamber via the effluent line. The electrode assembly, located in the effluent line, is exposed to the effluent exhausting from the process chamber. The electrode assembly, coupled to the RF power delivery network, receives an RF signal from the RF driver. The RF signal applied to the electrode assembly induces a plasma discharge within the electrode assembly and effluent line. A detector coupled to the electrode assembly detects various components of the delivered RF signal to determine end point of a chamber clean of the process chamber. The end point may be detected based on a change in impedance associated with the plasma discharge within the electrode assembly and effluent line.

As one of average skill in the art will appreciate, the term “substantially” or “approximately”, as may be used herein, provides an industry-accepted tolerance to its corresponding term. Such an industry-accepted tolerance ranges from less than one percent to twenty percent and corresponds to, but is not limited to, component values, integrated circuit process variations, temperature variations, rise and fall times, and/or thermal noise. As one of average skill in the art will further appreciate, the term “operably coupled”, as may be used herein, includes direct coupling and indirect coupling via another component, element, circuit, or module where, for indirect coupling, the intervening component, element, circuit, or module does not modify the information of a signal but may adjust its current level, voltage level, and/or power level. As one of average skill in the art will also appreciate, inferred coupling (i.e., where one element is coupled to another element by inference) includes direct and indirect coupling between two elements in the same manner as “operably coupled”. As one of average skill in the art will further appreciate, the term “compares favorably”, as may be used herein, indicates that a comparison between two or more elements, items, signals, etc., provides a desired relationship. For example, when the desired relationship is that signal 1 has a greater magnitude than signal 2, a favorable comparison may be achieved when the magnitude of signal 1 is greater than that of signal 2 or when the magnitude of signal 2 is less than that of signal 1.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

1. A system operable to measure an impedance of an effluent comprising:
a reactive specie delivery system;
a process chamber coupled to the reactive specie delivery system, the reactive specie delivery system operable to supply reactive species, the reactive species operable to volatilize a film in the process chamber;
an effluent line, wherein volatilized film effluent exhausts the process chamber via the effluent line;
an electrode assembly, located in the effluent line, the electrode exposed to the volatilized film effluent exhausting from the process chamber;
an ionization energy delivery network coupled to the electrode assembly, the ionization energy delivery network operable to apply an ionizing energy signal to the electrode assembly, wherein the ionizing energy signal applied at the electrode assembly induces a plasma discharge within the electrode assembly and effluent line; and
a detector coupled to the electrode assembly, the detector operable to detect an endpoint of a process being performed in the process chamber.

2. The system of claim 1, further comprising:
interface circuitry operably coupled to the reactive specie delivery system, the ionization energy delivery network and the detector, the interface circuitry operable to receive a trigger signal from the reactive specie delivery system, the ionization energy delivery network activated by the trigger signal.

3. The system of claim 1, further comprising:
interface circuitry operably coupled to the reactive specie delivery system, the ionization energy delivery network and the detector, the interface circuitry operable to supply an endpoint signal from the detector to the reactive specie delivery system, the reactive specie delivery system operable to secure the reactive species to the process chamber based on the endpoint signal.

4. The system of claim 1, wherein the process chamber is within a Chemical Vapor Deposition (CVD) tool.

5. The system of claim 1, wherein the CVD tool is operable to deposit a layer of a device selected from the group consisting of a semiconductor device, a textile, a display device and a photo-voltaic device.

6. The system of claim 1, wherein the detector samples at least one parameter selected from the group consisting of:
a voltage of the ionization energy;
a current of the ionization energy;
a phase of the ionization energy;
a delivered Power of the ionization energy;
impedance (Z) of the ionization energy;
resistance (R) of the ionization energy;
reactance (X) of the ionization energy; and
a generator forward or reflected power signal associated with ionization energy.

7. The system of claim 1, wherein the detector samples an impedance of the RF signal.

8. The system of claim 1, wherein the detector comprises processing circuitry operable to determine the endpoint of the process being performed in the process chamber based on at least one parameter selected from the group consisting of:
a voltage of the ionization energy;
a current of the ionization energy;
a phase of the ionization energy;
a delivered Power of the ionization energy;
impedance (Z) of the ionization energy;
resistance (R) of the ionization energy;
reactance (X) of the ionization energy; and
a generator forward or reflected power signal associated with ionization energy.

9. The system of claim 1, wherein the detector interfaces with the reactive specie delivery system, wherein processing circuitry of the reactive specie delivery system is operable to determine the endpoint of the process being performed in the process chamber based on signals supplied by the detector, the signals comprise at least one parameter selected from the group consisting of:
a voltage of the ionization energy;
a current of the ionization energy;
a phase of the ionization energy;
a delivered Power of the ionization energy;
impedance (Z) of the ionization energy;
resistance (R) of the ionization energy;
reactance (X) of the ionization energy; and
a generator forward or reflected power signal associated with ionization energy.

10. The system of claim 1, wherein the a process tool comprising the process chamber and coupled to the detector comprises processing circuitry operable to determine the endpoint of the process being performed in the process chamber based on signals supplied by the detector, the signals comprise at least one parameter selected from the group consisting of:
a voltage of the ionization energy;
a current of the ionization energy;
a phase of the ionization energy;
a delivered Power of the ionization energy;
impedance (Z) of the ionization energy;
resistance (R) of the ionization energy;
reactance (X) of the ionization energy; and
a generator forward or reflected power signal associated with ionization energy.

11. A method comprising:
coupling a remote plasma source to a process chamber;
supplying chamber cleaning gas from the remote plasma source to the process chamber;
exhausting chamber cleaning effluent from the process chamber via an effluent line;
exposing an electrode assembly, located in the effluent line, to the chamber cleaning effluent exhausting from the process chamber;
applying an RF signal to the electrode assembly, wherein the RF signal applied at the electrode assembly induces a plasma discharge within the electrode assembly and effluent line;
sampling at least one parameter associated with the plasma discharge within the electrode assembly and effluent line; and
determining an endpoint of a chamber clean based on the at least one parameter associated with the plasma discharge.

12. The method of claim 11, further comprising:
initiating the RF signal with a trigger signal from the remote plasma source.

13. The method of claim 11, further comprising:
securing the chamber clean based on the determined endpoint.

14. The method of claim 11, wherein securing the chamber clean based on the determined endpoint further comprises:
securing supplying chamber cleaning gas from the remote plasma source to the process chamber; and
securing the RF signal applied to the electrode assembly, wherein securing the RF signal applied to the electrode assembly terminates the plasma discharge within the electrode assembly and effluent line.

15. The method of claim 11, wherein the process chamber is within a Chemical Vapor Deposition (CVD) tool.

16. The method of claim 11, wherein the CVD tool is operable to deposit a layer of a device selected from the group consisting of a semiconductor device, a display device, textile, and a photo-voltaic device.

17. The method of claim 11, wherein sampling at least one parameter associated with the plasma discharge within the electrode assembly and effluent line comprises sampling at least one parameter selected from the group consisting of:
a voltage of the ionization energy;
a current of the ionization energy;
a phase of the ionization energy;
a delivered Power of the ionization energy;
impedance (Z) of the ionization energy;
resistance (R) of the ionization energy;
reactance (X) of the ionization energy; and
a generator forward or reflected power signal associated with ionization energy.

18. The method of claim 11, wherein processing circuitry within a process tool coupled to a detector operable to sample the at least one parameter associated with the plasma discharge within the electrode assembly and effluent line is operable to determine the endpoint of the chamber clean based on signals supplied by the detector.

19. The method of claim 11, wherein processing circuitry within a detector operable to sample the at least one parameter associated with the plasma discharge within the electrode assembly and effluent line is operable to determine the endpoint of the chamber clean based on signals supplied by the detector, the detector operable to interface with a process tool and supply an endpoint signal.

20. The method of claim 11, wherein the at least one parameter associated with the plasma discharge comprises an impedance.

21. A device comprising:
a substrate;
at least one deposited layer on the substrate, the at least one deposited layers processed within a chemical vapor deposition (CVD) process chamber of a CVD process tool,
the process chamber cleaned with chamber cleaning gas supplied from a remote plasma source coupled to the CVD process chamber, an endpoint of the chamber clean determined by detection circuitry located in a foreline coupled to the CVD process chamber, the foreline operable to exhaust chamber cleaning effluent from the CVD process chamber, the detection circuitry operable to induce and sample a plasma discharge within the chamber cleaning effluent within the foreline.

22. The device of claim 21, the device comprising at least on device selected from the group consisting of:
a semiconductor device;
a display device;
a photo-voltaic device; and
a textile product.

23. An endpoint detector comprising:
an electrode assembly, located in an effluent line, the electrode exposed to the effluent exhausting from the process chamber;
an RF driver coupled to the electrode assembly, the RF driver operable to apply an RF signal to the electrode assembly, wherein the RF signal applied at the electrode assembly induces a plasma discharge within the electrode assembly and effluent line; and
detection circuitry coupled to the electrode assembly, the detection circuitry operable to:
sample the plasma discharge within the electrode assembly and effluent line; and
determine an endpoint of an etch process based on the sampled plasma discharge.

24. The endpoint detector of claim 23, further comprising:
interface circuitry operably coupled to a remote plasma source, the RF driver and the detection circuitry, the interface circuitry operable:
to receive a trigger signal from the remote plasma source, the RF signal initiated by the RF driver based on the trigger signal; and
supply an endpoint signal from the detection circuitry to the reactive specie source, the reactive specie source operable to secure the reactive specie to the process chamber based on the endpoint signal.

25. The endpoint detector of claim 23, wherein the etch processes comprises:
a chamber clean;
a film removal; or
a layer etch.

26. An endpoint detector comprising:
an electrode assembly, located in an effluent line, the electrode exposed to the effluent exhausting from the process chamber;
an RF driver coupled to the electrode assembly, the RF driver operable to apply an RF signal to the electrode assembly, wherein the RF signal applied at the electrode assembly induces a plasma discharge within the electrode assembly and effluent line; and
detection circuitry coupled to the electrode assembly, the detection circuitry operable to:
sample the plasma discharge within the electrode assembly and effluent line;
interface circuitry operably coupled to a process tool, a remote plasma source, the RF driver and the detection circuitry, the interface circuitry operable:
to receive a trigger signal from the remote plasma source, the RF signal initiated by the RF driver based on the trigger signal; and
supply sample signals based on the plasma discharge to processing circuitry within the process tool, the processing circuitry operable to determine an endpoint signal from the sample signals, the processing circuitry operable to secure the reactive specie to the process chamber based on the endpoint signal.

27. A system operable to measure an impedance of a volatilized film effluent comprising:
a reactive specie delivery system;
a process chamber coupled to the reactive specie delivery system, the reactive specie delivery system operable to supply reactive species, the reactive species operable to volatilize a film in the process chamber;
an electrode assembly, the electrode exposed to the volatilized film effluent within the process chamber;
an ionization energy delivery network coupled to the electrode assembly, the ionization energy delivery network operable to apply an ionizing energy signal to the electrode assembly, wherein the ionizing energy signal applied at the electrode assembly induces a plasma discharge proximate to the electrode assembly; and
a detector coupled to the electrode assembly, the detector operable to detect a change in a chemical composition of the volatilized film effluent in the process chamber.

28. A system operable to measure an impedance of a volatilized chemistry comprising:
a reactive specie delivery system;
a process chamber coupled to the reactive specie delivery system, the reactive specie delivery system operable to supply reactive species, the reactive species operable to volatilize in the process chamber;
an electrode assembly, the electrode exposed to the volatilized chemistry within the process chamber;
an ionization energy delivery network coupled to the electrode assembly, the ionization energy delivery network operable to apply an ionizing energy signal to the electrode assembly, wherein the ionizing energy signal applied at the electrode assembly induces a plasma discharge proximate to the electrode assembly; and
a detector coupled to the electrode assembly, the detector operable to detect a change in a chemical composition of the volatilized chemistry in the process chamber.
